(19) United States
(12) Patent Application Publication
(10) Pub. No.: US 2026/0282298 A1
(43) Pub. Date: Sep. 17, 2026

(54) ELECTRIC VEHICLE

(71) Applicant: Toyota Jidosha Kabushiki Kaisha, Toyota-shi (JP)

(72) Inventor: Ryota KOIKE, Nisshin-shi (JP)

(73) Assignee: Toyota Jidosha Kabushiki Kaisha, Toyota-shi (JP)

(21) Appl. No.: 19/367,267

(22) Filed: Oct. 23, 2025

(30) Foreign Application Priority Data
Mar. 17, 2025 (JP) 2025-042324

(51) Int. Cl. H05K 7/20; B60L 1/08; B60L 53/20; B60L 53/302

(52) U.S. Cl. CPC H05K 7/20872; B60L 1/08; B60L 53/20; B60L 53/302; H05K 7/20272; H05K 7/20281; H05K 7/20327; H05K 7/20381; H05K 7/20881

(57) ABSTRACT

An electric vehicle includes an electric drive unit, one or more high-voltage modules connected to an electrical system to which a high-voltage battery is connected, and one or more thermal management modules connected to a heat transfer medium circulation circuit. The electric drive unit, the one or more high-voltage modules, and the one or more thermal management modules are installed inside a front compartment. The one or more high-voltage modules and the one or more thermal management modules are installed in a stacked state in a vehicle vertical direction above the electric drive unit such that the modules are sequentially positioned, from top to bottom, in order of increasing projected area when viewed from above the vehicle.

### CROSS-REFERENCE TO RELATED APPLICATIONS

This application is based upon and claims the benefit of priority from Japanese Patent Application No. 2025-042324, filed on Mar. 17, 2025, the entire contents of which are incorporated herein by reference.

### BACKGROUND

### 1. Field

The present disclosure relates to an electric vehicle.

### 2. Description of Related Art

Certain electric vehicles are equipped with an integrated electric drive unit that combines a traction motor and associated gears. JP2021-30833A discloses an electric vehicle in which an electric drive unit and a high-voltage module are installed within a front compartment located at a front portion of the vehicle.

In addition to the high-voltage module, other devices such as a thermal management module are also installed inside the front compartment. Since it is necessary to design the vehicle body so as to provide sufficient space in the front compartment to accommodate such devices, the flexibility in vehicle body design is restricted.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electric vehicle includes a front compartment provided in a front portion of the electric vehicle, a hood covering an upper side of the front compartment, an electric drive unit installed inside the front compartment and configured to generate a driving force in response to power supply from a high-voltage battery, one or more high-voltage modules installed inside the front compartment and connected to an electrical system to which the high-voltage battery is connected, and one or more thermal management modules installed inside the front compartment and connected to a heat transfer medium circulation circuit. The one or more high-voltage modules and the one or more thermal management modules are installed in a stacked state in a vehicle vertical direction above the electric drive unit such that the modules are sequentially positioned, from top to bottom, in order of increasing projected area when viewed from above the vehicle.

In another general aspect, an electric vehicle includes a front compartment provided in a front portion of the electric vehicle, a hood covering an upper side of the front compartment, an electric drive unit installed inside the front compartment and configured to generate a driving force in response to power supply from a high-voltage battery, one or more high-voltage modules installed inside the front compartment and connected to an electrical system to which the high-voltage battery is connected, and one or more thermal management modules installed inside the front compartment and connected to a heat transfer medium circulation circuit. The one or more high-voltage modules and the one or more thermal management modules are installed in a stacked state in a vehicle vertical direction above the electric drive unit such that a module having a smallest projected area when viewed from above the vehicle is located at an uppermost position.

Other features and aspects will be apparent from the following detailed description, the drawings, and the claims.

### BRIEF DESCRIPTION OF THE DRAWINGS

FIG. 1 is a schematic top view showing the layout of an electric vehicle according to one embodiment.

FIG. 2 is a schematic left side view showing the layout within the front compartment of the electric vehicle shown in FIG. 1.

FIG. 3 is a schematic top view showing the layout within the front compartment of the electric vehicle shown in FIG. 1.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

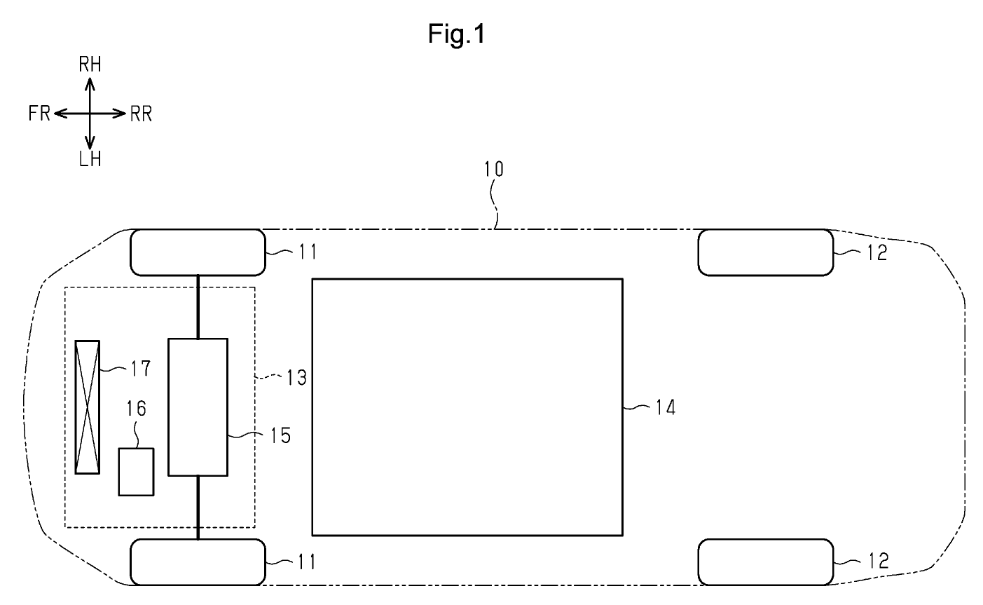

An electric vehicle 10 according to an embodiment will now be described with reference to FIGS. 1-3. In the drawings, FR represents the front of the vehicle 10, RR represents the rear of the vehicle 10, RH represents the right of the vehicle 10, LH represents the left of the vehicle 10, UP represents the upper side of the vehicle 10, and DW represents the lower side of the vehicle 10.

### Configuration of the Electric Vehicle 10

The electric vehicle 10 of the present embodiment shown in FIG. 1 includes four wheels, that is, left and right front wheels 11 and left and right rear wheels 12. The electric vehicle 10 is configured as a front-wheel-drive battery-powered vehicle that travels by driving left and right front wheels 11. The electric vehicle 10 has two electrical systems of a high-voltage system and a low-voltage system.

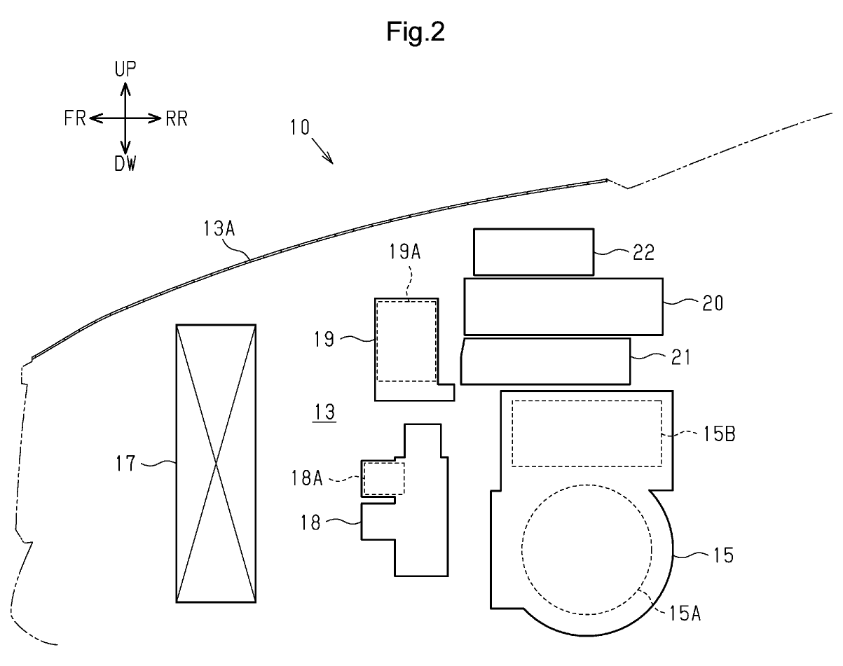

A front compartment 13 is provided in a front portion of the electric vehicle 10. The vehicle front portion refers to a portion of the electric vehicle 10 forward of a passenger compartment, in which occupants are seated. An upper side of the front compartment 13 is covered with an openable hood 13A (see FIG. 2). The front compartment 13 is configured such that the inside thereof can be accessed from above the front compartment 13 by opening the hood 13A. A high-voltage battery 14 connected to the high-voltage system of the electric vehicle 10 is installed under the floor of a portion of the electric vehicle 10 rearward of the front compartment 13. An electric drive unit 15 that generates a driving force of the electric vehicle 10 in response to power supply from the high-voltage battery 14 is installed inside the front compartment 13. In the present embodiment, the electric drive unit 15 is configured to drive the left and right front wheels 11. The electric drive unit 15 includes at least a motor 15A (see FIG. 2) that generates a driving force. In the present embodiment, the electric drive unit 15 is constructed as a module including a single case that accommodates the motor 15A, gears constituting a speed reduction mechanism and a differential mechanism, and an inverter 15B (see FIG. 2).

A low-voltage battery 16 and a radiator 17 are further installed inside the front compartment 13. The low-voltage battery 16 is a battery connected to a low-voltage system of the electric vehicle 10. The radiator 17 is a heat exchanger that cools the cooling water by heat exchange with outside air. The radiator 17 is installed in a front portion of the front compartment 13 so as to be easily exposed to the traveling wind. The low-voltage battery 16 is disposed in the front compartment 13 at a position forward of the electric drive unit 15 and rearward of the radiator 17.

Arrangement of a high-voltage module and a thermal management module

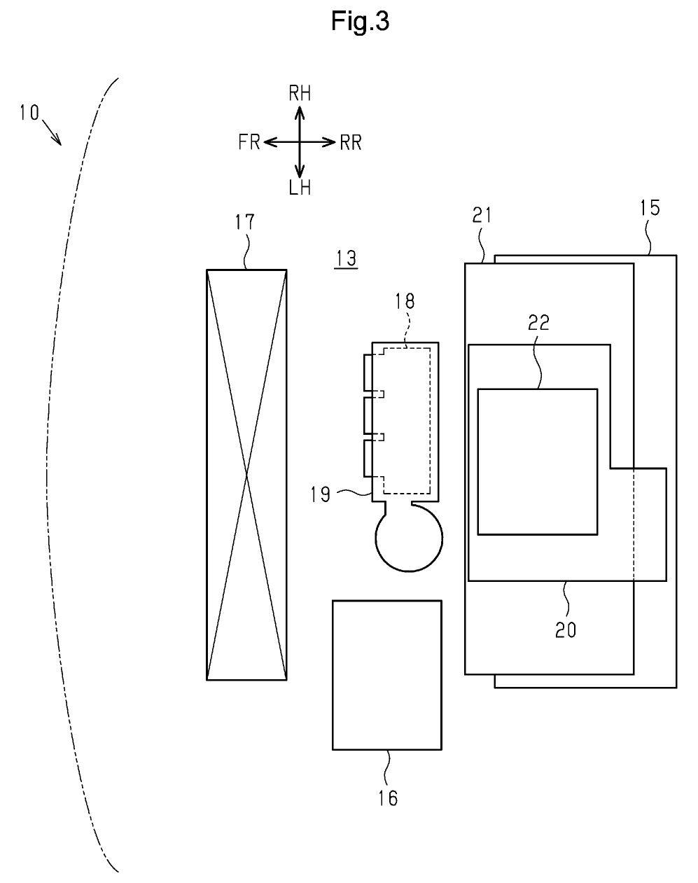

Next, the layout of the high-voltage module and the thermal management module inside the front compartment 13 of the electric vehicle 10 will be described with reference to FIGS. 2 and 3. FIG. 2 shows a layout of the inside of the front compartment 13 as viewed from the left side of the vehicle 10, and FIG. 3 shows a layout of the inside of the front compartment 13 as viewed from above the vehicle 10. The high-voltage module is a module connected to a high-voltage system of the electric vehicle 10. A thermal management module is a module for distributing a heat transfer medium. The electric vehicle 10 of the present embodiment includes, as heat transfer medium circulation circuits, two circuits of a water circuit for circulating cooling water and a refrigerant circuit for circulating a refrigerant for air conditioning. The radiator 17 is connected to the water circuit.

The electric vehicle 10 of the present embodiment includes, as thermal management modules installed inside the front compartment 13, a water module 18 that distributes cooling water, and a refrigerant module 19 that distributes a refrigerant. In the present embodiment, the water module 18 is constructed by combining components related to distribution of cooling water to the components to which the cooling water is supplied. The components to which the water module 18 distributes cooling water include the radiator 17, the high-voltage battery 14, and the electric drive unit 15. In the present embodiment, the water module 18 includes multiple electric pumps that deliver cooling water toward the respective components, and multiple switching valves that switch the flow of the cooling water toward the respective components.

The refrigerant module 19 is constructed by combining components related to distribution of refrigerant to the components to which the refrigerant is supplied. In the present embodiment, the refrigerant distributed by the refrigerant module 19 is used for air-conditioning of the passenger compartment, cooling of the high-voltage battery 14, or the like. In the present embodiment, the refrigerant module 19 includes multiple expansion valves that vaporize liquefied refrigerant and deliver the vaporized refrigerant to the respective components. In the present embodiment, the refrigerant module 19 includes a water-cooled condenser 19A that cools refrigerant through heat exchange with cooling water supplied from the water module 18, and a gas-liquid separator that performs gas-liquid separation of the cooled refrigerant. In the present embodiment, the water module 18 is provided with an electric pump 18A that delivers cooling water to the condenser 19A.

The electric vehicle 10 of the present embodiment includes a power distribution module 20 and an onboard charging module 21 as high-voltage modules installed inside the front compartment 13. The power distribution module 20 is a high-voltage module that distributes electric power of the high-voltage battery 14 to the respective high-voltage devices of the electric vehicle 10 including the inverter 15B. The onboard charging module 21 is a high-voltage module that controls charging of the high-voltage battery 14. In the present embodiment, the onboard charging module 21 is configured to include, in addition to a charging circuit for executing charge control, a step-down circuit that reduces power from the high-voltage system to a lower voltage and supplies it to the low-voltage system.

A high-voltage heater module 22 is further installed inside the front compartment 13. The high-voltage heater module 22 is one of thermal management modules connected to the cooling water circulation circuit. The high-voltage heater module 22 is configured to electrically heat the cooling water using electric power of the high-voltage battery 14. In the present embodiment, the high-voltage heater module 22 is configured to heat the cooling water that has passed through the condenser 19A of the refrigerant module 19. The cooling water heated by the high-voltage heater module 22 is used for, for example, heating the passenger compartment or heating the high-voltage battery 14. The high-voltage heater module 22 is configured to have a smaller projected area than the power distribution module 20 when viewed from above the vehicle 10.

In the present embodiment, the water module 18 and the refrigerant module 19 are installed forward of the electric drive unit 15. In the present embodiment, the water module 18 and the refrigerant module 19 are arranged in the vehicle vertical direction such that the refrigerant module 19 is positioned above the water module 18. The low-voltage battery 16 is disposed on the left side of the water module 18 and the refrigerant module 19.

The power distribution module 20 and the onboard charging module 21, which are two high-voltage modules, are installed in a stacked state in the vehicle vertical direction above the electric drive unit 15 such that the modules are sequentially positioned, from top to bottom, in order of increasing projected area when viewed from above the vehicle 10. In the present embodiment, the onboard charging module 21, which has a larger projected area as viewed from above the vehicle 10 than the power distribution module 20, is installed below the power distribution module 20.

In the present embodiment, in addition to the two high-voltage modules, the high-voltage heater module 22 is also installed above the electric drive unit 15. The high-voltage heater module 22, which has a smaller projected area than the power distribution module 20 when viewed from above the vehicle 10, is disposed above the power distribution module 20.

### Operation of the Embodiment

In the electric vehicle 10 of the present embodiment, the power distribution module 20, the onboard charging module 21, and the high-voltage heater module 22 are installed above the electric drive unit 15 in a state of being stacked on each other in the vehicle vertical direction. By installing the electric drive unit 15, the power distribution module 20, the onboard charging module 21, and the high-voltage heater module 22 in a state of being stacked on each other in the vehicle vertical direction in this way, it is possible to efficiently arrange them in a limited space inside the front compartment 13. However, when such an arrangement is adopted, the shape of the hood 13A is restricted in order to avoid the hood 13A from interfering with the module installed inside the front compartment 13. As a result, the design and aerodynamic performance of the electric vehicle 10 may be impaired.

In order to address this, in the electric vehicle 10 of the present embodiment, the above-described three modules are installed in a stacked state in the vehicle vertical direction above the electric drive unit 15 such that the modules are sequentially positioned, from top to bottom, in order of increasing projected area when viewed from above the vehicle 10. Therefore, the restriction imposed on the shape of the hood 13A by each module installed above the electric drive unit 15 is reduced.

### Advantages of the Embodiment

The electric vehicle 10 of the present embodiment has the following effects.

(1) In the electric vehicle 10 of the present embodiment, the three modules of the power distribution module 20, the onboard charging module 21, and the high-voltage heater module 22 are installed above the electric drive unit 15 inside the front compartment 13. The three modules are installed in a state of being stacked on one another in the vehicle vertical direction such that the module having the smallest projected area as viewed from above the vehicle 10 is located at the uppermost position. By arranging the modules in this way, it is possible to reduce restrictions on the shape of the hood 13A for avoiding interference with the modules. Therefore, it is possible to efficiently arrange the thermal/high-voltage module in the front compartment 13 while ensuring the flexibility in vehicle body design.

(2) The above-described three modules are installed in a stacked state in the vehicle vertical direction above the electric drive unit 15 such that the modules are sequentially positioned, from top to bottom, in order of increasing projected area when viewed from above the vehicle 10. This makes it possible to further reduce the restriction on the shape of the hood 13A.

(3) In the front compartment 13 of the electric vehicle 10 of the present embodiment, the water module 18 and the refrigerant module 19 are provided as thermal management modules separate from the high-voltage heater module 22. The water module 18 and the refrigerant module 19 are installed forward of the electric drive unit 15. By arranging the thermal management modules separately above and forward of the electric drive unit 15 in this way, the arrangement efficiency of the thermal management modules inside the front compartment 13 can be increased. In addition, according to the above-described arrangement, since the traveling wind easily hits the water module 18 and the refrigerant module 19, the cooling efficiency thereof is improved.

### Other Embodiments

The above-described embodiment may be modified as follows. The above-described embodiment and the following modifications can be combined if the combined modifications remain technically consistent with each other.

The types and the number of the high-voltage modules and the thermal management modules installed above the electric drive unit 15 may be changed as appropriate.

In the above-described embodiment, each module is installed above the electric drive unit 15 such that a module having a larger projected area as viewed from above the vehicle 10 is positioned lower. The arrangement order of the other modules in the vehicle vertical direction may be arbitrarily changed as long as the module having the smallest projected area as viewed from above the vehicle 10 is disposed at the uppermost position.

As long as the electric drive unit 15 includes a motor 15A that generates a driving force of the electric vehicle 10 by receiving a supply of electric power from the high-voltage battery 14, other configurations may be appropriately changed. For example, the electric drive unit 15 may be configured separately from the inverter 15B, or may be configured separately from the gears constituting the speed reduction mechanism and the difference mechanism.

The high-voltage battery 14, the low-voltage battery 16, and the radiator 17 may be disposed at positions different from those in the above-described embodiment.

The electric vehicle 10 may be configured as a four wheel drive vehicle in which the rear wheels 12 are driven by an electric drive unit other than the electric drive unit 15 installed inside the front compartment 13 or by an engine.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An electric vehicle, comprising:
a front compartment provided in a front portion of the electric vehicle;
a hood covering an upper side of the front compartment;
an electric drive unit installed inside the front compartment and configured to generate a driving force in response to power supply from a high-voltage battery;
one or more high-voltage modules installed inside the front compartment and connected to an electrical system to which the high-voltage battery is connected; and
one or more thermal management modules installed inside the front compartment and connected to a heat transfer medium circulation circuit,
wherein the one or more high-voltage modules and the one or more thermal management modules are installed in a stacked state in a vehicle vertical direction above the electric drive unit such that the modules are sequentially positioned, from top to bottom, in order of increasing projected area when viewed from above the vehicle.

2. The electric vehicle according to claim 1, wherein
the one or more thermal management modules installed above the electric drive unit are one or more first thermal management modules, and
one or more second thermal management modules different from the one or more first thermal management modules are installed forward of the electric drive unit inside the front compartment.

3. The electric vehicle according to claim 2, wherein
the one or more second thermal management modules include:
a water module configured to distribute cooling water in a cooling water circulation circuit; and
a refrigerant module configured to distribute a refrigerant for air conditioning in a refrigerant circulation circuit; and
the one or more first thermal management modules include a high-voltage heater module configured to electrically heat the cooling water.

4. The electric vehicle according to claim 1, wherein the one or more high-voltage modules include:
a power distribution module configured to distribute power of the high-voltage battery; and
an onboard charging module configured to charge the high-voltage battery.

5. An electric vehicle, comprising:
a front compartment provided in a front portion of the electric vehicle;
a hood covering an upper side of the front compartment;
an electric drive unit installed inside the front compartment and configured to generate a driving force in response to power supply from a high-voltage battery;
one or more high-voltage modules installed inside the front compartment and connected to an electrical system to which the high-voltage battery is connected; and
one or more thermal management modules installed inside the front compartment and connected to a heat transfer medium circulation circuit,
wherein the one or more high-voltage modules and the one or more thermal management modules are installed in a stacked state in a vehicle vertical direction above the electric drive unit such that a module having a smallest projected area when viewed from above the vehicle is located at an uppermost position.

6. The electric vehicle according to claim 5, wherein
the one or more thermal management modules installed above the electric drive unit are one or more first thermal management modules, and
one or more second thermal management modules different from the one or more first thermal management modules are installed forward of the electric drive unit inside the front compartment.

7. The electric vehicle according to claim 6, wherein
the one or more second thermal management modules include:
a water module configured to distribute cooling water in a cooling water circulation circuit; and
a refrigerant module configured to distribute a refrigerant for air conditioning in a refrigerant circulation circuit; and
the one or more first thermal management modules include a high-voltage heater module configured to electrically heat the cooling water.

8. The electric vehicle according to claim 5, wherein the one or more high-voltage modules include:
a power distribution module configured to distribute power of the high-voltage battery; and
an onboard charging module configured to charge the high-voltage battery.
